(19) United States
(12) Patent Application Publication
(10) Pub. No.: US 2018/0340979 A1
(43) Pub. Date: Nov. 29, 2018

(54) SYSTEM AND METHOD FOR REDUCING POWER CONSUMPTION IN SCANNABLE CIRCUIT

(71) Applicant: Samsung Electronics Co., Ltd., Suwon-si (KR)

(72) Inventor: Matthew BERZINS, Cedar Park, TX (US)

(21) Appl. No.: 15/663,580

(22) Filed: Jul. 28, 2017

Related U.S. Application Data
(60) Provisional application No. 62/511,318, filed on May 25, 2017.

(51) Int. Cl. G01R 31/3185; H03K 19/00; H03K 19/173

(52) U.S. Cl. CPC G01R 31/318575; G01R 31/025; H03K 19/173; H03K 19/0016

(57) ABSTRACT

A scannable circuit element includes a data path and a scan-data path that are respectively selected in response to a first operational mode and a second operational mode. The scan-data path includes an input element having an input node, an output node, a first power node and a second power node. A signal path between the input node and the output node is part of the scan-data path. The first power node is coupled to a first voltage potential, and the second power node is coupled to a mode-control signal that is at substantially the first voltage potential in the first operational mode and that is at substantially a second voltage potential in the second operational mode. In the second operational mode, the scannable element exhibits no switching current and no leakage current.

### CROSS-REFERENCE TO RELATED APPLICATION

This patent application claims the priority benefit under 35 U.S.C. § 119(e) of U.S. Provisional Patent Application No. 62/511,318, filed on May 25, 2017, the disclosure of which is incorporated herein by reference in its entirety.

### TECHNICAL FIELD

The subject matter disclosed herein relates to scannable circuits. More particularly, the subject matter disclosed herein relates to a system and a method for reducing power and leakage currents in a scannable circuit.

### BACKGROUND

Scan-chain testing is a design-for-testability (DFT) technique that embeds hardware components in an integrated circuit (IC) design to detect manufacturing faults in the IC. The testability features of DFT components may be configured as a sequential element within a sequential logic path (e.g., a flip-flop, a latch, etc.) that may operate in a scannable mode (i.e., a test mode). Such DFT components are extraneous with respect to the normal (non-test mode) operation of the IC and may waste power due to switching current and/or leakage current during a normal operation of the IC.

### SUMMARY

An embodiment provides a scannable circuit element that may include a data path and a scan-data path. The data path may be selected in response to a first operational mode, and the scan-data path may be selectable in response to a second operational mode in which the second operational mode is complementary to the first operational mode. The scan-data path may include an input element that may have an input node, an output node, a first power node and a second power node. A signal path between the input node and the output node of the input element may be part of the scan-data path. The first power node may be coupled to a first voltage potential, and the second power node being may be coupled to a mode-control signal that is at substantially the first voltage potential in the first operational mode and that is at substantially a second voltage potential in the second operational mode. The second voltage potential may be different from the first voltage potential and the second voltage potential may correspond to a common ground potential. Substantially no current flows in the input element between the first power node and the second power node in the first operational mode, and a power supply current flows in the input element between the first power node and the second power node in the second operational mode. The input element may include a buffer, an inverter, a logic gate or a multiplexer.

An embodiment provides a scannable circuit element that may include a logic storage element, a data path and a scan-data path. The logic storage element may include an input. The data path may be coupled to the input of the logic storage element and the data path may be selected in response to a first operational mode. The scan-data path may be coupled to the input of the logic storage element and the scan-data path may be selectable in response to a second operational mode in which the second operational mode may be complementary to the first operational mode. The scan-data path may include an input element that may have an input node, an output node, a first power node and a second power node. A signal path between the input node and the output node of the input element may be part of the scan-data path. The first power node may be coupled to a first voltage potential, and the second power node may be coupled to a mode-control signal that is at substantially the first voltage potential in the first operational mode and that is at substantially a second voltage potential in the second operational mode. The second voltage potential may be different from the first voltage potential and the second voltage potential may corresponds to a common ground potential. Substantially no current flows in the input element between the first power node and the second power node in the first operational mode, and a power supply current flows in the input element between the first power node and the second power node in the second operational mode.

One embodiment provides a method to select a scan mode for a scannable circuit element that may include: selecting a data path in a scannable circuit element in response to a first operational mode in which the scannable circuit element may include the data path and a scan-data path; and selecting the scan-data path in response to a second operational mode in which the second operational mode may be complementary to the first operational mode, and in which the scan-data path may include an input element that may have an input node, an output node, a first power node and a second power node in which a signal path between the input node and the output node of the input element may be part of the scan-data path, the first power node may be coupled to a first voltage potential, and the second power node may be coupled to a mode-control signal that is at substantially the first voltage potential in the first operational mode and that is at substantially a second voltage potential in the second operational mode, and in which the second voltage potential may be different from the first voltage potential and the second voltage potential corresponding to a common ground potential.

### BRIEF DESCRIPTION OF THE DRAWINGS

In the following section, the aspects of the subject matter disclosed herein will be described with reference to exemplary embodiments illustrated in the figures, in which:

FIG. 1A depicts a block diagram of an example embodiment of a scan chain;

FIG. 1B depicts a block diagram of an example embodiment of a scan-chain flip-flop that may include an inverter and a multiplexer in a scan-data path;

FIG. 1C depicts a block diagram of a portion of a scan chain in which a delay circuit, or a buffer chain, may be inserted into the scan-data path between a launch flip-flop and a scan-capture flip-flop;

FIG. 1D depicts a block diagram of a portion of a scan chain in which a buffer chain may be inserted into the scan-data path internally to a scan-capture flip-flop;

FIG. 2A depicts a block diagram of one embodiment of a buffer chain that may be used for either of the buffer chains depicted in FIG. 1C or 1D;

FIG. 2B depicts a block diagram of another embodiment of a buffer chain that may be used for either of the buffer chains depicted in FIG. 1C or 1D;

FIG. 3 depicts a block diagram of one example embodiment of a buffer chain that may be part of a scan chain and that provides reduced power consumption and reduced leakage current according to the subject matter disclosed herein;

FIG. 4 depicts a block diagram of another example embodiment of a buffer chain that may be part of a scan chain and that provides a reduced power consumption and a reduced leakage current according to the subject matter disclosed herein;

FIG. 5 depicts a block diagram of still another example embodiment of a buffer chain that may be part of a scan chain and that provides reduced power consumption according to the subject matter disclosed herein;

FIG. 6 depicts a schematic diagram of one example embodiment of a front end of a scan-chain flip-flip according to the subject matter disclosed herein; and

FIG. 7 depicts an electronic device that comprises one or more integrated circuits (chips) comprising a scannable circuit for reducing power and leakage currents according to the subject matter disclosed herein.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail not to obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not be necessarily all referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing particular exemplary embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement the teachings of particular embodiments disclosed herein.

Unless otherwise defined, all terms (including technical and scientific terms) used herein have the same meaning as commonly understood by one of ordinary skill in the art to which this subject matter belongs. For example, the term “mod” as used herein means “modulo.” It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The subject matter disclosed herein provides a scannable circuit element that may include a data path and a scan-data path. The data path may be selected in response to a first operational mode, whereas the scan-data path may be selectable in response to a second operational mode. In one embodiment, the scan-data path may include an input element that may include an input node, an output node, a first power node and a second power node. A signal path between the input node and the output node of the input element may be part of the scan-data path. The first power node may be coupled to a first voltage potential, and the second power node may be coupled to a mode-control signal that is at substantially the first voltage potential in the first operational mode and that is at substantially a second voltage potential in the second operational mode. If the scannable circuit element is in the second operational mode, the scannable element exhibits no switching current and no leakage current.

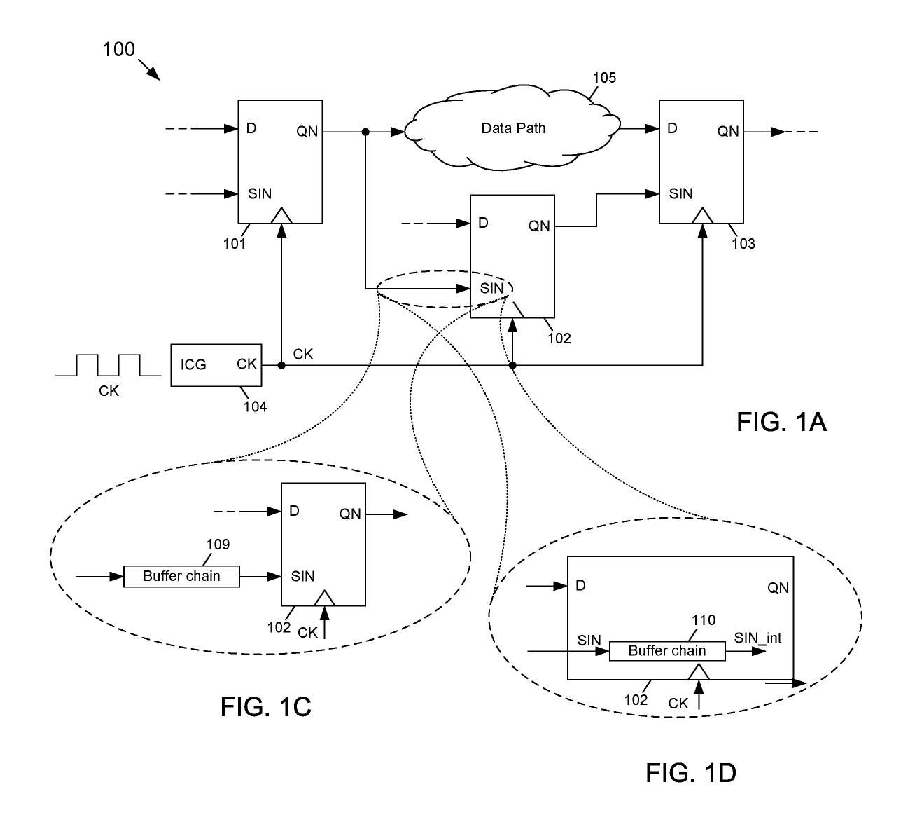

FIG. 1A depicts a block diagram of an embodiment of a scan chain 100. The scan chain 100 may include a launch flip-flop 101, one or more scan-capture flip-flops 102, one or more data-capture flip-flops 103, and an integrated clock gater (ICG) 104. Each of the scan-chain flip-flops 101-103 may include a data D input, a scan pin (SIN) input, a clock input (∧), and an output QN. The scan chain 100 may be configured to be in parallel with a data path 105, which is operable for normal (non-test mode) operations.

A scannable MS flip-flop 101-103 may include some internal scan-signal drive so circuits, such as buffers and inverters, may be used to drive and/or delay a signal arrival at a scan input pin SIN. For example, the pin SIN may be internally driven so circuits internal to the flip-flop are not externally slew-rate dependent. In some embodiments, a scan-chain flip-flop 101-103 may also be configured to include an inverter 106 and a multiplexer 107 in a scan-data path, and a master-slave (MS) flip-flop circuit 108, such as depicted in FIG. 1B. The multiplexer 107 may be controlled by a scan-test mode enable (SE) to select either the data D input (non-test mode, i.e., SE=0=GND) or the SIN input (test mode, i.e., SE=1=VDD). The output of the multiplexer 107 may be a MLN0 signal, which is coupled to an input to the MS flip-flop circuit 108. Such conventional circuits internal to a scannable flip-flop are, however, always switching and have leakage current, thereby resulting in a significant amount of power consumption.

The scan chain 100 may be configured so that the output of one scan-chain flip-flop is chained, or connected, to the next geographically closest scan-chain flip-flop input, which results in a minimal delay between the output and the input. Such a minimal delay may cause set-up and/or hold-time problems at the input of the next scan-chain flip-flop.

A conventional approach to reduce the set-up and/or hold-time problems is to include a delay circuit between the output of one scan-chain flip-flop and the input of the next scan-chain flip-flop. FIG. 1C depicts a block diagram of a portion of the scan chain 100 in which a delay circuit, or a buffer chain 109, may be inserted into the scan-data path between the launch flip-flop 101 and the scan-capture flip-flop 102. The buffer chain 109 is external to the scan-capture flip-flop 102. FIG. 1D depicts a block diagram of a portion of the scan chain 100 so that a buffer chain 110 is inserted into the scan-data path internally to the scan-capture flip-flop 102. It should be noted that an inverter 106 and a multiplexer circuit 107, such as depicted in FIG. 1B, are not shown in either of FIG. 1C or 1D.

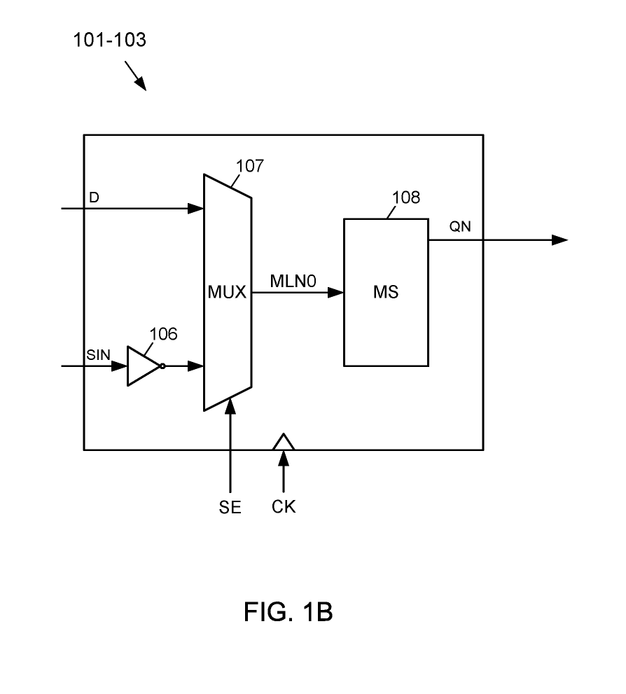

FIG. 2A depicts a block diagram of one embodiment of a buffer chain 201 that may be used for either the buffer chain 109 or the buffer chain 110. In FIG. 2A, the buffer chain 201 may include one or more inverters 202 and 203 connected in series, of which only two inverters are shown. An output signal Sin_int of the inverter 203 may be input to a scan pin of a flip-flop (not shown). The power supply nodes of both inverters 202 and 203 are connected between VDD and ground (GND). A scan-in signal SIN is input to the inverter 202. The inverter 202 outputs a signal SI_int, which is an inverted version of the signal SIN. The SI_int signal is input to the inverter 203. The inverter 203 outputs a signal SIN_int, which is an inverted version of the signal SI_int.

FIG. 2B depicts a block diagram of another embodiment of a buffer chain 205 that may be used for either the buffer chain 109 or the buffer chain 110. In FIG. 2B, the buffer circuit 205 may include an AND gate 206, and one or more inverters 207 and 208 connected in series, of which only two inverters are shown. In an alternative embodiment, the AND gate 206 may be replaced by a NAND gate. An output signal Sin_int of the inverter 208 may be input to a scan pin of a flip-flop (not shown). The power supply nodes of the AND gate 206 and the inverters 207 and 208 are connected between VDD and GND. A scan-in signal SIN is input to one input of the AND gate 206. A scan-test enable signal SE may be input to the other input of the AND gate 206. The AND gate 206 outputs a signal SING, which is a gated version of the signal SIN and that that is controlled (i.e., gated) by the signal SE. The signal SING is input to the inverter 207, which outputs a signal SI_int. The signal SI_int is input to the inverter 208, and the inverter 208 outputs a signal SIN_int, which is an inverted version of the SI_int signal.

The buffer chain 205 uses less power in the non-test mode than the buffer chain 201 because the scan-test enable signal SE gates the SIN signal and no switching occurs in the inverters 207 and 208 in the scan-test enable mode. The buffer chain 201 always switches in the scan-test enable mode thereby consuming power. Additionally, the gate 206 in the chain buffer 205 uses about an additional 10% area within a scan-chain flip-flop. Both the buffer chains 201 and 205 exhibit leakage current, even when switching is gated/disabled by an AND/NAND gate.

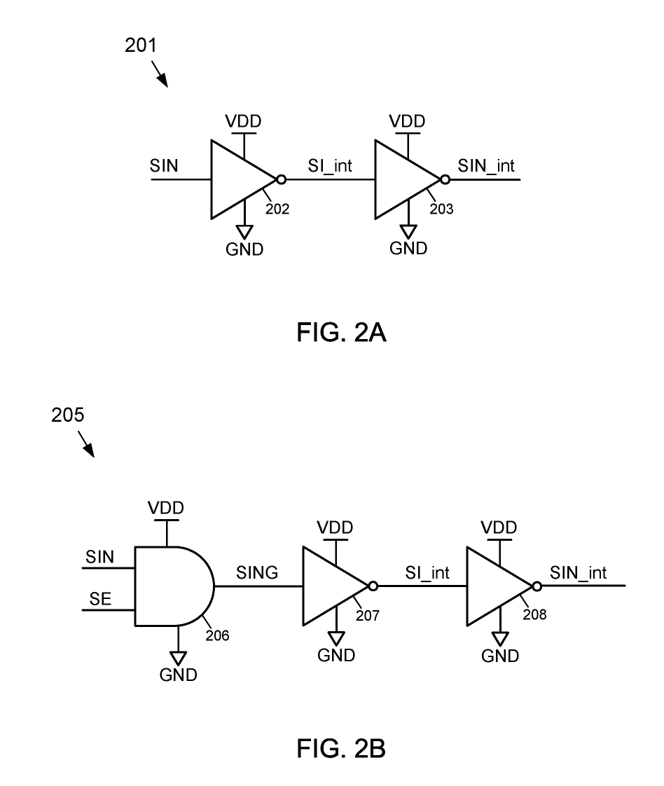

FIG. 3 depicts a block diagram of one example embodiment of a buffer chain 300 that may be part of a scan chain and that provides reduced power consumption and reduced leakage current according to the subject matter disclosed herein. The buffer chain 300 may include one or more inverters 301 and 302 connected in series, of which only two inverters are shown. An output signal Sin_int of the inverter 302 may be input to a scan pin of a flip-flop (not shown). An inverter 303 may be configured to output an inverted scan-enable signal SEN based on a scan-enable signal SE. The signal SEN may be connected as a common ground node to the inverter 301, which receives a scan-in signal SIN as an input. The power supply nodes of the inverter 301 may be connected to VDD and the signal SEN. The power supply nodes of the inverter 302 may be connected between VDD and GND.

If the signal SEN is low (i.e., scan-test mode true, and SE=1 and SEN=0=GND), and the signal SIN is input to the inverter 301, the inverter 301 outputs a signal SI_int, which is an inverted version of the signal SIN. The signal SI_int is input to the inverter 302. The inverter 302 outputs a signal SIN_int, which is an inverted version of the signal SI_int. If the signal SEN is high (i.e., scan-test mode false, and SE=0 and SEN=1=VDD), the inverter 301 does not pass the signal SIN, and the inverter 302 does not switch. Accordingly, if the signal SEN signal is high (i.e., scan-test mode false), the buffer chain 300 has a reduced power consumption (no switching current), and the inverter 301 exhibits no leakage current.

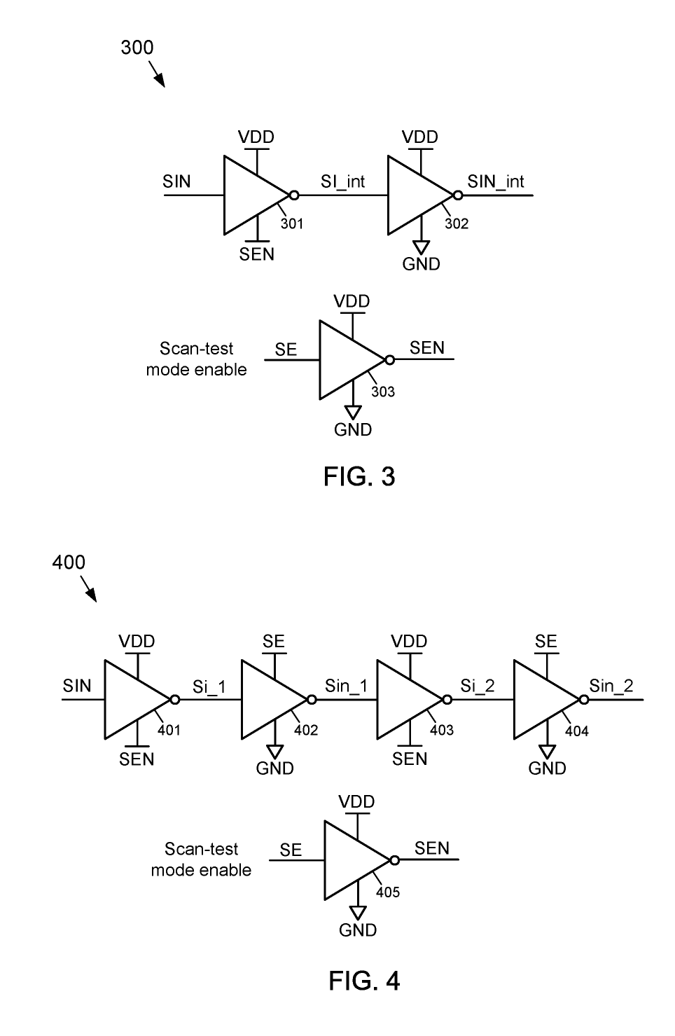

FIG. 4 depicts a block diagram of another example embodiment of a buffer chain 400 that may be part of a scan chain and that provides a reduced power consumption and a reduced leakage current according to the subject matter disclosed herein. The buffer chain 400 may include one or more inverters 401, 402, 403, and 404 connected in series, of which only four inverters are shown. An output signal Sin_2 of the inverter 404 may be input to a scan pin of a flip-flop (not shown). An inverter 405 may be configured to output an inverted scan-enable signal SEN based on a scan-enable signal SE. The signal SEN may be coupled as a common ground node to the ground nodes of the inverters 401 and 403, and the signal SE may be coupled to the VDD nodes of the inverters 402 and 404.

If the signal SE is high and the signal SEN signal is low (i.e., scan-test mode true, and SE=1 and SEN=0=GND), and the signal SIN is input to the inverter 401, and the inverter 401 outputs a signal SI_int, which is an inverted version of the signal SIN. The inverters 402-404 respectively output a signal Sin_1, a signal Si_2, and a signal Sin_2. If the signal SE is low and the signal SEN is high (i.e., scan-test mode false, and SE=0 and SEN=1=VDD), all four inverters 401-404 are removed from the scan-data signal path, and the buffer chain 400 provides reduced power consumption (i.e., no switching current), and exhibits no leakage current. That is, if the signal SE is low, there is no leakage current in the inverters 401 and 403, which have a ground node connected to the signal SEN. Similarly, if the signal SE is low, there is no leakage current in the inverters 402 and 404, which have a VDD supply node connected to SE. The signals Si_1 and Si_2 are always at VDD so that any leakage current that flows, flows back to VDD (i.e., no leakage current). If the scan-test mode is not enabled, the buffer chain 400 does not switch (no power consumption). Moreover, buffer chain 400 includes no additional area or gates as compared to a conventional buffer chain, such as conventional buffer chain 205 in FIG. 2B.

Table 1 below sets forth signal levels for the buffer chain 400 depicted in FIG. 4. In some embodiments, the inverter 401 of the buffer chain 400 may output what is referred to as a “weak drive” signal. That is, the inverter 401 may output a signal VDD—Vtn, in which Vtn is a transistor gate threshold voltage of the output transistor of the inverter 401. This condition is noted in Table 1.

TABLE 1
Signal Levels For Buffer Chain 400.

| | CASE | Si_1 | Sin_1 | Si_2 | Sin_2 |
|---|---|---|---|---|---|
| SE = 0 | SIN = 0 | VDD | GND | VDD | GND |
| SEN = VDD | SIN = 1 | VDD-Vtn | GND | VDD | GND |
| SE = 1 | SIN = 0 | VDD | GND | VDD | GND |
| SEN = GND | SIN = 1 | GND | VDD | GND | VDD |

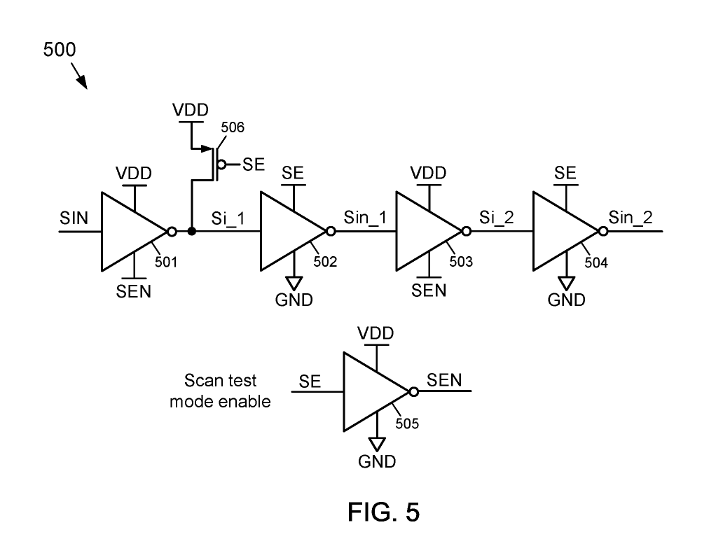

FIG. 5 depicts a block diagram of another example embodiment of a buffer chain 500 that may be part of a scan chain and that provides reduced power consumption according to the subject matter disclosed herein. The buffer chain 500 provides no leakage current while preventing a “weak drive” condition. The buffer chain 500 may include one or more inverters 501, 502, 503, and 504 connected in series, of which only four inverters are shown. An output signal Sin_2 of the inverter 504 may be input to a scan pin of a flip-flop (not shown). An inverter 505 may be configured to output an inverted scan-enable signal SEN that is based on a scan-enable signal SE. Similar to the buffer chain 400 depicted in FIG. 4, the signal SEN may be coupled to the common ground nodes of the inverters 501 and 503, and the signal SE may be coupled to the VDD nodes of the inverters 502 and 504. The buffer chain 500 operates similarly to the buffer chain 400.

A “weak drive” condition may be avoided by including a transistor 506 coupled between VDD and the output of the inverter 501. In one embodiment, the transistor 506 may be a positive metal oxide semiconductor (PMOS) FET in which a source terminal of the transistor 506 may be coupled to VDD, a gate terminal of the transistor 506 may be coupled to the signal SE, and a drain terminal of the transistor 506 may be coupled to the output of a scan-chain element that receives the signal SIN. In FIG. 5, the scan-chain element that receives the signal SIN is the inverter 501, although other circuit configurations for a buffer chain according to the subject matter disclosed herein are possible. Table 2 below sets forth signal levels for the buffer chain 500 depicted in FIG. 5.

TABLE 2
Signal Levels For Buffer Chain 500.

| | CASE | Si_1 | Sin_1 | Si_2 | Sin_2 |
|---|---|---|---|---|---|
| SE = 0 | SIN = 0 | VDD | GND | VDD | GND |
| SEN = VDD | SIN = 1 | VDD | GND | VDD | GND |
| SE = 1 | SIN = 0 | VDD | GND | VDD | GND |
| SEN = GND | SIN = 1 | GND | VDD | GND | VDD |

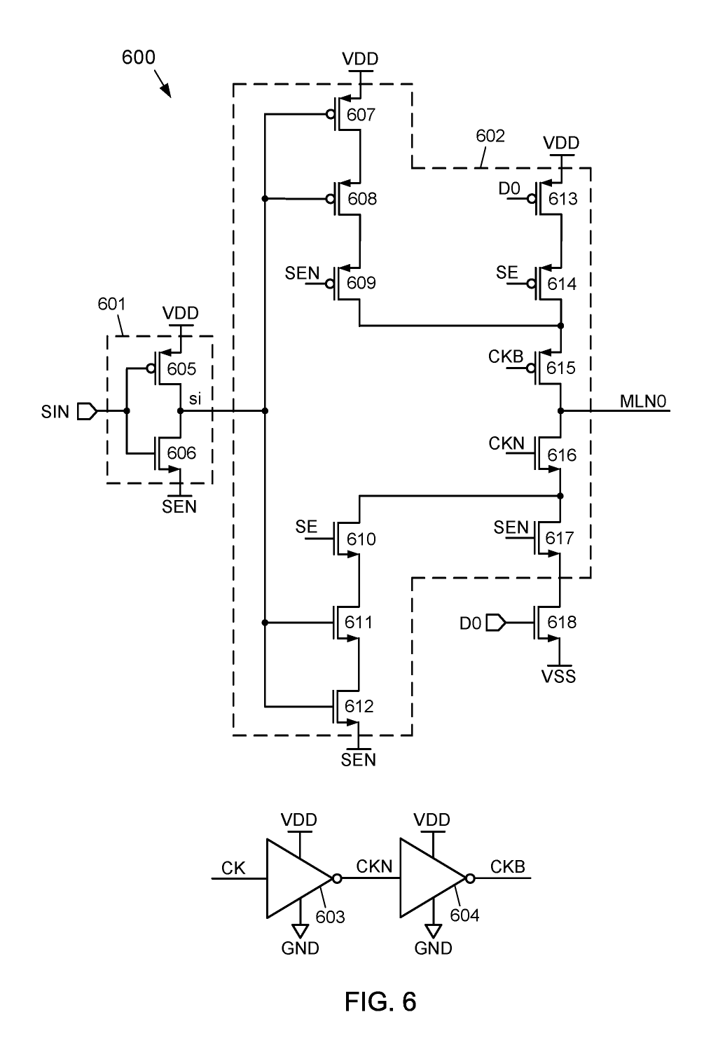

FIG. 6 depicts a schematic diagram of one example embodiment of a front end 600 of a scan-chain flip-flip according to the subject matter disclosed herein. The front end 600 includes an inverter 601 and a multiplexer 602. By way of example, FIG. 1B depicts an example of a front end of a scan-chain flip-flop that includes a conventional inverter and a conventional multiplexer. FIG. 6 also depicts that the front end 600 may include an inverter 603 and an inverter 604 connected in series that are configured to output a clock signal CKN and a clock signal CKB that are based on an input clock signal CK.

The inverter 601 may include a p-channel field effect transistor (FET) 605 and an n-channel FET 606. A source of the FET 605 may be connected to VDD, and a drain of the FET 605 may be connected to the drain of the FET 606. A source of the FET 606 may be connected to the signal SEN. The signal SEN may be generated from a scan-test enable signal SE, such as depicted in FIGS. 3-5. A scan-data input signal SIN is input to the gates of the FETS 605 and 606. An output signal si of the inverter 601 is output at the common connection of the drain of FET 605 and the drain of FET 606.

The multiplexer 602 may include FETs 607-617. A source of the FET 607 may be connected to VDD, and a drain of the FET 607 may be connected to a source of the FET 608. A drain of the FET 608 may be connected to the source of the FET 609. The drain of the FET 609 may be connected to a common connection between the drain of FET 614 and the source of FET 615. The gates of the FETs 607 and 608 may be connected to the signal si. The gate of the FET 609 may be connected to the signal SEN.

The source of the FET 612 may be connected to the signal SEN, and the drain of the FET 612 may be connected to the source of the FET 611. The drain of the FET 611 may be connected to the source of the FET 610, and the drain of the FET 610 may be connected to a common connection between the source of the FET 616 and the drain of the FET 617. The gates of the FETs 611 and 612 may be connected to the signal si. The gate of the FET 610 may be connected to the signal SE.

The source of the FET 613 may be connected to VDD, and the drain of the FET 613 may be connected to the source of the FET 614. The drain of the FET 614 may be connected to the common connection between the drain of the FET 609 and the source of the FET 615. The gate of the FET 613 may be connected to an input signal D0, and the gate of the FET 614 may be connected to the signal SE.

The source of the FET 618 may be connected to VSS, and the drain of the FET 618 may be connected to the source of the FET 617. The drain of the FET 617 may be connected to the common connection between the drain of the FET 609 and the source of the FET 616. The gate of the FET 617 may be connected to the signal SEN. The gate of the FET 618 may be connected to the input signal D0.

The source of the FET 615 may be connected to the common connection between the drain of FET 609 and the drain of the FET 614. The drain of the FET 615 may be connected to the drain of the FET 616, and the source of the FET 616 may be connected to the common connection between the drain of the FET 610 and the drain of the FET 617. The gate of the FET 615 may be connected to the clock signal CKB, and the gate of the FET 616 may be connected to the clock signal CKN. The output of the multiplexer 603 is output from the common connection of the source of the FET 615 and the drain of the FET 616.

If the front end 600 depicted in FIG. 6 is in a scan-test mode, the signal SE will be high and the signal SEN will be low, in which case the FETs 606, 609-612 and 614 will be turned on, and the FET 617 will be turned off. If the FETs 606, 609-612 and 614 are turned on, the scan-data input signal SIN propagates through the inverter 601 and the multiplexer 602, and is output as the signal MLN0. The signal MLN0 may be input to an MS flip-flop (not shown in FIG. 6).

If the front end 600 is not in the scan-test mode (i.e., a normal mode), the signal SE will be low and the signal SEN will be high, in which case the FETs 606, 609-612 and 614 will be turned off, and the FET 617 will be turned on. If the FETs 606, 609-612 and 614 are turned off, no signal flows from the scan-data input SIN to the output signal MLN0. Instead, the data signal D0 is output as the signal MLN0. Further, if the FETs 606, 609-612 and 614 are turned off, the common ground node of the FETs 606 and 612 is at VDD, which prevents leakage current from flowing in the inverter 601 and the multiplexer 602.

It may be noted that the output inverter 601 may in some cases exhibit a “weak drive” condition. Such a weak drive condition may be prevented by using a transistor coupled between VDD and the output of the inverter 601, as described in connection with the buffer chain 500 depicted in FIG. 5.

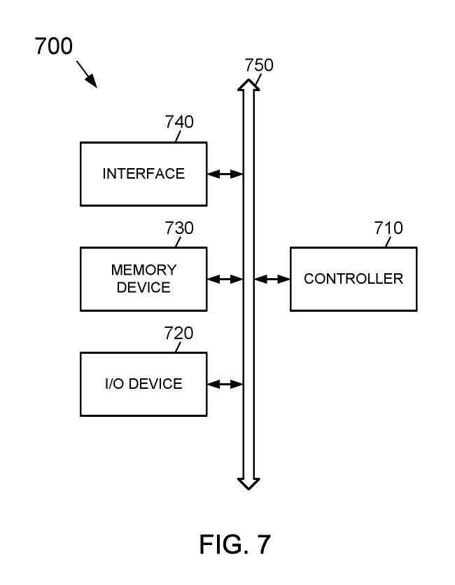

FIG. 7 depicts an electronic device 700 that comprises one or more integrated circuits (chips) comprising a scannable circuit for reducing power and leakage currents according to the subject matter disclosed herein. Electronic device 700 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 700 may comprise a controller 710, an input/output device 720 such as, but not limited to, a keypad, a keyboard, a display, a touch-screen display, a camera, and/or an image sensor, a memory 730, and an interface 740 that are coupled to each other through a bus 750. The controller 710 may comprise, for example, at least one microprocessor, at least one digital signal process, at least one microcontroller, or the like. The memory 730 may be configured to store a command code to be used by the controller 710 or a user data. Electronic device 700 and the various system components comprising electronic device 700 may comprise a scannable circuit for reducing power and leakage currents according to the subject matter disclosed herein. The interface 740 may be configured to include a wireless interface that is configured to transmit data to or receive data from a wireless communication network using a RF signal. The wireless interface 740 may include, for example, an antenna, a wireless transceiver and so on. The electronic system 700 also may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service-Time Division Duplex (UMTS-TDD), High Speed Packet Access (HSPA), Evolution Data Optimized (EVDO), Long Term Evolution-Advanced (LTE-Advanced), Multichannel Multipoint Distribution Service (MMDS), and so forth.

As will be recognized by those skilled in the art, the innovative concepts described herein can be modified and varied over a wide range of applications. Accordingly, the scope of claimed subject matter should not be limited to any of the specific exemplary teachings discussed above, but is instead defined by the following claims.

What is claimed is:

1. A scannable circuit element, comprising:
a data path, the data path being selected in response to a first operational mode; and
a scan-data path, the scan-data path being selectable in response to a second operational mode, the second operational mode being complementary to the first operational mode, the scan-data path comprising:
an input element comprising an input node, an output node, a first power node and a second power node, a signal path between the input node and the output node of the input element being part of the scan-data path, the first power node being coupled to a first voltage potential, and the second power node being coupled to a mode-control signal that is at substantially the first voltage potential in the first operational mode and that is at substantially a second voltage potential in the second operational mode, the second voltage potential being different from the first voltage potential and the second voltage potential corresponding to a common ground potential.

2. The scannable circuit element of claim 1, wherein substantially no current flows in the input element between the first power node and the second power node in the first operational mode, and a power supply current flows in the input element between the first power node and the second power node in the second operational mode.

3. The scannable circuit element of claim 1, wherein the input element comprises a buffer, an inverter, a logic gate or a multiplexer.

4. The scannable circuit element of claim 1, wherein the scan-data path further comprises a second element, the second element comprising an input node, an output node, a first power node and a second power node, a signal path between the input node and the output node of the second element being part of the scan-data path, the first power node of the second element being coupled to a second mode-control signal that is at substantially the second voltage potential in the first operational mode and that is at substantially the first voltage potential in the second operational mode, and the second power node of the second element being coupled to the second voltage potential.

5. The scannable circuit element of claim 4, wherein substantially no current flows in the second element between the first power node and the second power node in the first operational mode, and a power supply current flows in the second element between the first power node and the second power node in the second operational mode.

6. The scannable circuit element of claim 4, wherein the second element comprises a buffer, an inverter, a logic gate or a multiplexer.

7. The scannable circuit element of claim 1, further comprising a logic storage element comprising an input node coupled to the data path and to the scan-data path, the logic storage element receiving a signal on the data path in the first operational mode and receiving a signal on the scan-data path in the second operational mode.

8. A scannable circuit element, comprising:
a logic storage element comprising an input;
a data path coupled to the input of the logic storage element, the data path being selected in response to a first operational mode; and
a scan-data path coupled to the input of the logic storage element, the scan-data path being selectable in response to a second operational mode, the second operational mode being complementary to the first operational mode, the scan-data path comprising:
an input element comprising an input node, an output node, a first power node and a second power node, a signal path between the input node and the output node of the input element being part of the scan-data path, the first power node being coupled to a first voltage potential, and the second power node being coupled to a mode-control signal that is at substantially the first voltage potential in the first operational mode and that is at substantially a second voltage potential in the second operational mode, the second voltage potential being different from the first voltage potential and the second voltage potential corresponding to a common ground potential.

9. The scannable circuit element of claim 8, wherein substantially no current flows in the input element between the first power node and the second power node in the first operational mode, and a power supply current flows in the input element between the first power node and the second power node in the second operational mode.

10. The scannable circuit element of claim 8, wherein the input element comprises a buffer, an inverter, a logic gate or a multiplexer, and
wherein the logic storage element comprises a flip-flop.

11. The scannable circuit element of claim 8, wherein the scan-data path further comprises a second element, the second element comprising an input node, an output node, a first power node and a second power node, a signal path between the input node and the output node of the second element being part of the scan-data path, the first power node of the second element being coupled to a second mode-control signal that is at substantially the second voltage potential in the first operational mode and that is at substantially the first voltage potential in the second operational mode, and the second power node of the second element being coupled to the second voltage potential.

12. The scannable circuit element of claim 11, wherein substantially no current flows in the second element between the first power node and the second power node in the first operational mode, and a power supply current flows in the second element between the first power node and the second power node in the second operational mode.

13. The scannable circuit element of claim 11, wherein the second element comprises a buffer, an inverter, a logic gate or a multiplexer, and
wherein the logic storage element comprises a flip-flop.

14. The scannable circuit element of claim 8, wherein the logic storage element receives a signal on the data path in the first operational mode and receives a signal on the scan-data path in the second operational mode.

15. A method to select a scan mode for a scannable circuit element, the method comprising:
selecting a data path in a scannable circuit element in response to a first operational mode, the scannable circuit element comprising the data path and a scan-data path; and
selecting the scan-data path in response to a second operational mode, the second operational mode being complementary to the first operational mode, the scan-data path comprising:
an input element comprising an input node, an output node, a first power node and a second power node, a signal path between the input node and the output node of the input element being part of the scan-data path, the first power node being coupled to a first voltage potential, and the second power node being coupled to a mode-control signal that is at substantially the first voltage potential in the first operational mode and that is at substantially a second voltage potential in the second operational mode, the second voltage potential being different from the first voltage potential and the second voltage potential corresponding to a common ground potential.

16. The method of claim 15, wherein substantially no current flows in the input element between the first power node and the second power node in the first operational mode, and a power supply current flows in the input element between the first power node and the second power node in the second operational mode.

17. The method of claim 15, wherein the input element comprises a buffer, an inverter, a logic gate or a multiplexer.

18. The method of claim 15, wherein the scan-data path further comprises a second element, the second element comprising an input node, an output node, a first power node and a second power node, a signal path between the input node and the output node of the second element being part of the scan-data path, the first power node of the second element being coupled to a second mode-control signal that is at substantially the second voltage potential in the first operational mode and that is at substantially the first voltage potential in the second operational mode, and the second power node of the second element being coupled to the second voltage potential.

19. The method of claim 18, wherein substantially no current flows in the second element between the first power node and the second power node in the first operational mode, and a power supply current flows in the second element between the first power node and the second power node in the second operational mode.

20. The method of claim 15, wherein the data path and the scan-data path are coupled to an input node of a logic storage element,
the method further comprising receiving at the input node of the logic storage element a signal on the data path in the first operational mode and a signal on the scan-data path in the second operational mode.
